(19) United States
(12) Patent Application Publication
(10) Pub. No.: US 2025/0239451 A1
(43) Pub. Date: Jul. 24, 2025

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Yejin KIM, Suwon-si (KR); Yunju CHAE, Suwon-si (KR); Jooyoung CHUNG, Suwon-si (KR); Seunghyun KIM, Suwon-si (KR)

(21) Appl. No.: 19/010,392

(22) Filed: Jan. 6, 2025

(30) Foreign Application Priority Data
Jan. 24, 2024 (KR) 10-2024-0010863

(51) Int. Cl. H01L 21/027; C08G 16/02; H01L 21/308; H01L 21/311; H01L 21/3213

(52) U.S. Cl. CPC H01L 21/0271; C08G 16/0268; H01L 21/3081; H01L 21/31144; H01L 21/32139

(57) ABSTRACT

A hardmask composition, a hardmask layer including a cured product of the hardmask composition, and a method of forming patterns that uses the hardmask layer including a cured product of the hardmask composition, the hardmask composition includes a polymer including a structural unit represented by Chemical Formula 1; and a solvent,

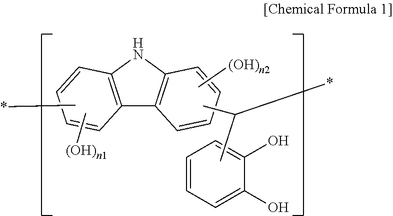

### CROSS-REFERENCE TO RELATED APPLICATION

This application claims priority to and the benefit of Korean Patent Application No. 10-2024-0010863 filed in the Korean Intellectual Property Office on Jan. 24, 2024, the entire contents of which are incorporated herein by reference.

### BACKGROUND

### 1. Field

Embodiments relate to a hardmask composition, a hardmask layer, and a method of forming patterns using the hardmask compositions.

### 2. Description of the Related Art

Recently, the semiconductor industry has developed an ultra-fine technique having a pattern of several to several tens nanometer size. Such ultrafine techniques may use effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a polymer including a structural unit represented by Chemical Formula 1; and a solvent,

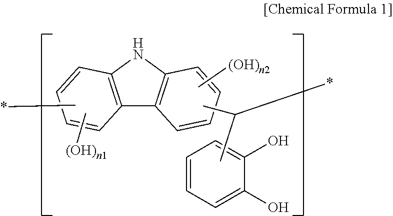

wherein, in Chemical Formula 1, n1 and n2 are each independently 0 or 1, n1+n2 is 1 or 2, and * is a linking point.
n1 may be 0 and n2 may be 1.

The polymer may further include a structural unit represented by Chemical Formula 2,

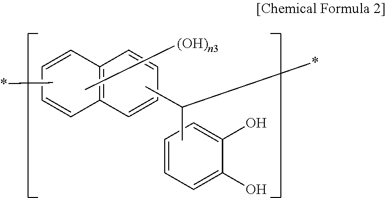

in Chemical Formula 2, n3 may be an integer of 1 to 6, and * is a linking point.
n3 may be 1 or 2.

Chemical Formula 2 may be represented by Chemical Formula 2-1, in which * is a linking point,

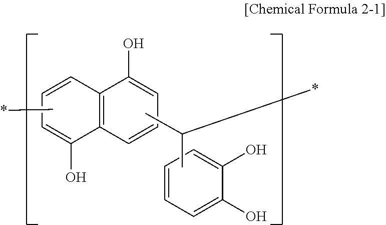

Chemical Formula 1 may be represented by Chemical Formula 1-1 or Chemical Formula 1-2, in which * is a linking point,

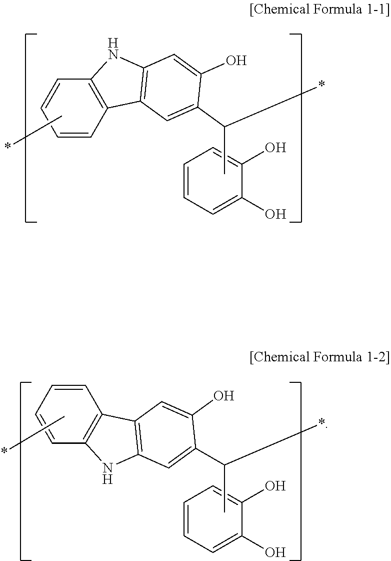

Chemical Formula 1 may be represented by Chemical Formula 1-3 or Chemical Formula 1-4, in which * is a linking point,

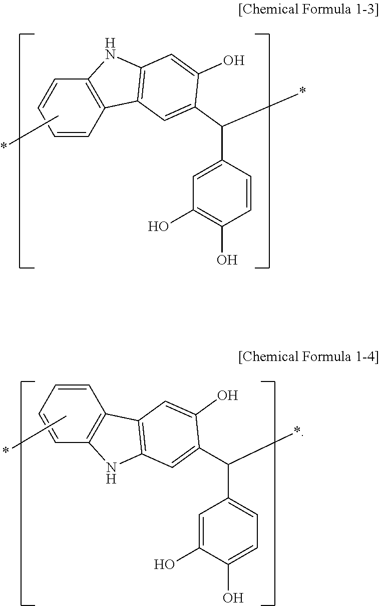

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, N-methyl-2-pyrrolidone, acetylacetone, or ethyl 3-ethoxypropionate.

The embodiments may be realized by providing a hardmask layer including a cured product of the hardmask composition according to an embodiment.

The embodiments may be realized by providing a method of forming patterns, the method including providing a material layer on a substrate, applying the hardmask composition according to an embodiment to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed part of the material layer.

The heat-treating may be performed at about 100° C. to about 1,000° C.

### DETAILED DESCRIPTION

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. As used herein, the term “or” is not necessarily an exclusive term, e.g., “A or B” would include A, B, or A and B. As used herein, unless described otherwise, “*” is a linking point.

Example embodiments will hereinafter be described in detail, and may be easily performed by a person skilled in the art. However, this disclosure may be embodied in many different forms and is not construed as limited to the example embodiments set forth herein.

As used herein, when a definition is not otherwise provided, “substituted” may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, the polymer may include an oligomer or a polymer.

Unless otherwise specified in the present specification, the weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In the semiconductor industry, a size of chips may be reduced. Accordingly, the line width of the resist patterned in lithography technology may have a size of several tens of nanometers. A height that can withstand the line width of the resist pattern may be limited, and there are cases where the resists may not have sufficient resistance in the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching. Therefore, the hardmask layer may exhibit etch resistance to withstand the etching process required for pattern transfer.

Some other hardmask layers may be formed in a chemical or physical deposition method, and may have low economic efficiency due to a large-scale equipment and a high process cost. Therefore, a method of forming a hardmask layer by a spin-coating technique has recently been considered. The spin-coating technique may be easier to process than other methods and in addition, may help secure excellent gap-fill characteristics and planarization characteristics of a hardmask layer formed therefrom. In a hardmask layer formed using the spin-coating technique, the etch resistance could be somewhat lowered. Accordingly, a hardmask composition according to an embodiment may be applied using the spin-coating technique and may secure equivalent etch resistance to that of the hardmask layer formed in the chemical or physical deposition method.

In order to help improve the etch resistance of the hardmask layer, maximizing a carbon content of a hardmask composition may be considered. As a carbon content of a polymer included in the hardmask composition is maximized, solubility in solvents could decrease. According to an embodiment, the carbon content maximization of a polymer included in the hardmask composition may not only improve the etch resistance of the hardmask layer formed of the hardmask composition but may also help secure high solubility of the polymer in the solvents.

The hardmask composition according to some embodiments may include a polymer including a structural unit represented by Chemical Formula 1, and a solvent.

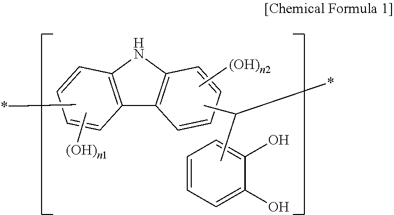

In Chemical Formula 1, n1 and n2 may each independently be, e.g., 0 or 1. n1+n2 may be 1 or 2. * is a linking point.

The composition according to some embodiments may include a polymer including carbazole moiety (having two benzene rings) and a phenyl group on which two hydroxy groups may be substituted, as shown in Chemical Formula 1, thereby reducing a carbon content in the composition. Accordingly, the hardmask layer formed from the composition according to some embodiments may help secure excellent etch resistance. In addition, the carbazole moiety includes nitrogen including a lone pair of electrons, the phenyl group is substituted with a hydroxy group, and the film density and film characteristics of the hardmask layer formed therefrom may be improved without reducing solubility of the polymer in solvents.

In an implementation, n1 of Chemical Formula 1 may be 0 and n2 may be 1. In an implementation, n1 may be 1 and n2 may be 0.

In an implementation, the polymer may further include a structural unit represented by Chemical Formula 2.

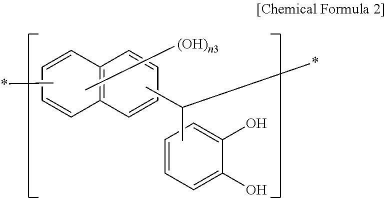

In Chemical Formula 2, n3 may be, e.g., an integer of 1 to 6. * is a linking point.

In an implementation, the polymer included in the composition may further include the structural unit represented by Chemical Formula 2, and the film density and film strength of the hardmask layer formed from the composition may be further improved.

In an implementation, n3 may be an integer of 1 to 4, e.g., an integer of 1 to 3, 1, or 2.

In an implementation, Chemical Formula 1 may be represented by Chemical Formula 1-1 or Chemical Formula 1-2.

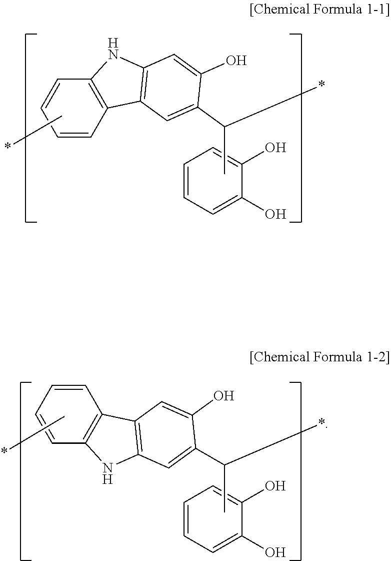

In an implementation, Chemical Formula 1 may be represented by Chemical Formula 1-3 or Chemical Formula 1-4.

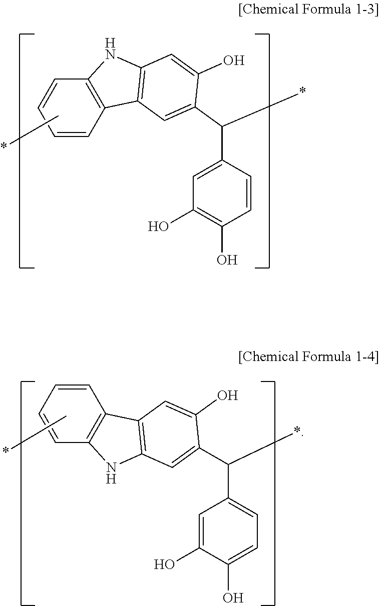

In an implementation, Chemical Formula 2 may be represented by Chemical Formula 2-1.

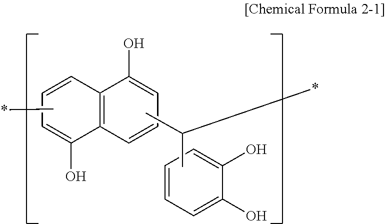

In an implementation, the polymer may have a weight average molecular weight of, e.g., about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,200 g/mol to about 50,000 g/mol, or about 1,200 g/mol to about 10,000 g/mol. Maintaining the weight average molecular weight within the above ranges may help ensure that the carbon content and solubility in the solvent of the hardmask composition including the above polymer may be adjusted and optimized.

In an implementation, the polymer may be included in an amount of, e.g., about 0.1 wt % to about 30 wt %, based on a total weight of the hardmask composition. In an implementation, the polymer may be included in an amount of, e.g., about 0.2 wt % to about 30 wt %, about 0.5 wt % to about 30 wt %, about 1 wt % to about 30 wt %, about 1.5 wt % to about 25 wt %, or about 2 wt % to about 20 wt %. Maintaining the amount of the polymer within the above ranges may help ensure that a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, N-methyl-2-pyrrolidone, acetylacetone, ethyl 3-ethoxypropionate, or the like. In an implementation solvent may include a suitable solvent, as long as it has sufficient solubility or dispersibility with respect to the polymer.

In an implementation, hardmask composition may further include an additive, e.g., a surfactant, a crosslinking agent, a thermal acid generator, or a plasticizer.

The surfactant may include, e.g., a fluoroalkyl-based compound, alkylbenzenesulfonate, alkylpyridinium salt, polyethylene glycol, a quaternary ammonium salt, or the like.

The crosslinking agent may include, e.g., a melamine, a substituted urea, or polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

In an implementation, the thermal acid generator may include an acid compound, e.g., p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include, e.g., providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer may be a material to be finally patterned, e.g., a metal layer such as an aluminum layer or a copper layer, a semiconductor layer such as a silicon layer, or an insulating layer such as a silicon oxide layer or a silicon nitride layer. The material layer may be formed through, e.g., a chemical vapor deposition process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour. In an implementation, the heat-treating may be performed under an atmosphere of air or nitrogen, or an atmosphere having an oxygen concentration of about 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, about 30 seconds to about 30 minutes, about 30 seconds to about 10 minutes, or 30 seconds to about 5 minutes.

In an implementation, the heat-treating may include a second heat-treating process that is consecutively performed, e.g., at about 100° C. to about 1,000° C., about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, or about 30 seconds to 5 minutes. In an implementation, the first and second heat-treating processes may be performed under an air or nitrogen atmosphere, or may be performed under an atmosphere with an oxygen concentration of about 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include at least one of a first heat-treating process, a second heat-treating process, a UV/Vis curing process, and a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas. In an implementation, the etching gas may include, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Polymer

### Synthesis Example 1

2-hydroxycarbazole (4.27 g, 0.02 mol) and 3,4-dihydroxybenzaldehyde (3.22 g, 0.02 mol) were added to a 250 ml flask. Subsequently, p-toluene sulfonic acid monohydrate (0.89 g, 0.005 mol) was dissolved in 11 g of propylene glycol monomethyl ether acetate (PGMEA), and this solution was added to the flask and then, stirred at 100° C. After taking a sample from the polymerization reactant every hour to measure its weight average molecular weight, when the weight average molecular weight reached 1,800 g/mol to 2,000 g/mol, a reaction of the sample was completed. When the polymerization reaction was completed, the resultant was cooled to ambient temperature, an intermediate product therefrom was added to 300 g of distilled water and 30 g of methanol and then, vigorously stirred and allowed to stand. After removing a supernatant therefrom and then, dissolving precipitates therein in 100 g of propylene glycol monomethyl ether acetate (PGMEA), the solution was vigorously stirred by using 30 g of methanol and 300 g of distilled water and then, allowed to stand (primary). After removing the supernatant therefrom again, the precipitates therein were dissolved in 80 g of propylene glycol monomethyl ether acetate (PGMEA). The primary and secondary processes were regarded as one purification process, which was repeated ten times. A polymer completed with the purification was dissolved in 80 g of propylene glycol monomethylether acetate (PGMEA), and the methanol and distilled water remaining in the solution were removed under a reduced pressure to obtain Polymer 1 including a structural unit represented by Chemical Formula 1-3.

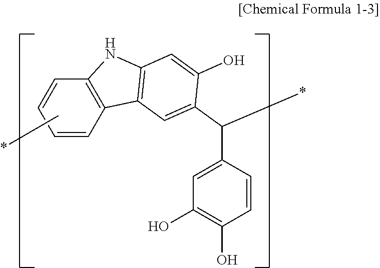

### Synthesis Example 2

Polymer 2, including the structural unit represented by Chemical Formula 1-3 and a structural unit represented by Chemical Formula 2-2 was obtained in the same manner as in Synthesis Example 1 except that 0.02 mol of 1,5-dihydroxynaphthalene was further added thereto as a reactant.

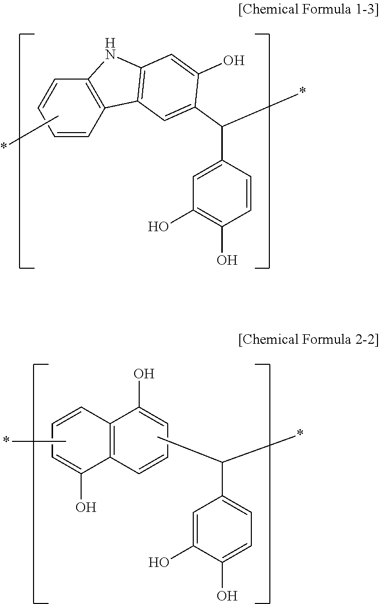

### Comparative Synthesis Example 1

Comparative Polymer 1, including a structural unit represented by Chemical Formula 3, was obtained in the same manner as in Synthesis Example 1 except that 2.34 g (0.02 mol) of indole was used instead of the 2-hydroxycarbazole.

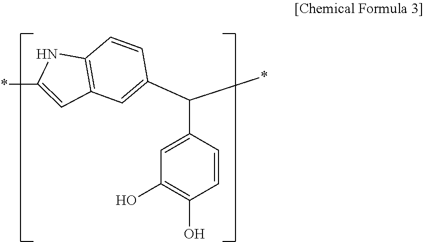

### Preparation of Hardmask Composition

### Example 1

A hardmask composition was prepared by dissolving 1 g of Polymer 1 according to Synthesis Example 1 in 10 g of a mixed solvent of propylene glycolmonomethylether acetate (PGMEA) and propylene glycol monomethyl ether (PGME) (7:3 (v/v)) and then, filtering the solution with a 0.1 m TEFLON (tetrafluoroethylene) filter.

### Example 2

A hardmask composition was prepared in the same manner as in Example 1 except that Polymer 2 was used instead of Polymer 1.

### Comparative Example

A hardmask composition was prepared in the same manner as in Example 1 except that Comparative Polymer 1 was used instead of Polymer 1.

### Evaluation 1: Film Density Evaluation

Each of the hardmask compositions according to Examples 1 to 2 and the Comparative Example was spin-coated on a silicon wafer and then, heat-treated on a hot plate at 400° C. for 2 minutes to form a 4,000 Å-thick thin film. The thin film was measured with respect to film density by using an X-ray diffraction equipment made by Malvern Panalytical Ltd. The results are shown in Table 1.

TABLE 1

| | Film density (g/cm³) |
|---|---|
| Example 1 | 1.50 |
| Example 2 | 1.54 |
| Comparative Example | 1.43 |

Referring to Table 1, the hardmask compositions according to Examples 1 and 2 exhibited excellent film density, compared with the hardmask composition according to the Comparative Example.

### Evaluation 2: Film Strength Evaluation

Each of the hardmask compositions according to Examples 1 to 2 and the Comparative Example was spin-coated to be 5,000 Å thick on a silicon wafer and then, heat-treated on a hot plate at 400° C. for 2 minutes to form a thin film. Subsequently, the thin film was measured with respect to hardness (H) by using a nanoindenter (cube corner tip, Pmax=300 μN). The results are shown in Table 2.

TABLE 2

| | Hardness [Gpa] |
|---|---|
| Example 1 | 0.94 |
| Example 2 | 0.95 |
| Comparative Example | 0.8 |

Referring to Table 2, each hardmask layer formed of the hardmask compositions of Examples 1 to 2 exhibited excellent hardness, compared with that formed of the hardmask composition of the Comparative Example. In other words, the hardmask compositions of the Examples provided a hardmask layer with excellent film strength, compared with the hardmask composition of the Comparative Example.

### Evaluation 3: Solubility Evaluation

5 g of each of the polymers according to Synthesis Examples 1 to 2 and Comparative Synthesis Example was uniformly dissolved in 45 g of a PGMEA solvent to prepare a 10% solution, which was filtered with a 0.1 μm TEFLON (tetrafluoroethylene) filter. After the filtering, a solid content thereof was measured with respect to mass in a loss-on-drying method. If there was a mass difference from that of each starting material polymer, ‘X’ is given, and if there was no mass difference from that of each starting material polymer, ‘∘’ is given.

TABLE 3

| | Solid mass change |
|---|---|
| Synthesis Example 1 | ∘ |
| Synthesis Example 2 | ∘ |
| Comparative Synthesis Example | ∘ |

Referring to Table 3, the polymers according to Synthesis Examples 1 to 2 exhibit no deteriorated solubility in a solvent.

### Evaluation 4: Heat Resistance Evaluation

Each hardmask composition according to Examples 1 to and 2 and the Comparative Example was spin-coated on a silicon wafer. The formed film was baked on a hot plate at 240° C. for 1 minute to measure a thickness and then, at 400° C. for 2 minutes to measure a thickness again. The thicknesses measured at two temperatures were used to calculate a thickness decrease rate of the thin film according to Calculation Equation 1 and thus relatively quantify heat resistance of the hardmask layer. The results are shown in Table 4.

$$Thin film thickness reduction rate ( \% ) = [ ( Thin film thickness after baking at 240 °C . - Thin film thickness after baking at 400 °C . ) / Thin film thickness after baking at 240 °C . ] \times 100 ( \% ) \qquad [ Calculation Equation 1 ]$$

TABLE 4

| | Thin film thickness reduction rate (%) |
|---|---|
| Example 1 | 17 |
| Example 2 | 13 |
| Comparative Example | 29 |

Referring to Table 4, each hardmask of the hardmask compositions according to Examples 1 to 2, compared with that of the hardmask composition according to the Comparative Example, exhibited a low thin film thickness decrease rate under the conditions. It may be seen that the hardmasks of the compositions of the Examples exhibited excellent heat resistance, compared with that of the composition of the Comparative Example.

### Evaluation 5: Etch Resistance Evaluation

Each of the hardmask compositions of Examples 1 to 2 and the Comparative Example was spin-on coated on a patterned silicon wafer and heat-treated at 400° C. for 120 seconds to form a hardmask film to measure a film thickness by using a ST5000 thin film thickness meter manufactured by K-MAC. Subsequently, the thin film was dry-etched respectively for 60 seconds and for 120 seconds by using N₂/O₂ mixed gas (50 mT/300 W/10O₂/50N₂) and CFx gas (100 mT/600 W/42CF₄/600Ar/15O₂) to measure a thickness again. The thicknesses of the thin film before and after the dry etching thin film and etching time were used to calculate a bulk etch rate (BER) according to Calculation Equation 2, and the results are shown in Table 5.

$$Etch rate ( Å / sec ) = ( Initial thin film thickness - Thin film thickness after etching ) ( Å ) / Etching time ( sec ) \qquad [ Calculation Equation 2 ]$$

TABLE 5

Bulk etch rate (Å/s)

| | N₂/O₂ etch | CFx etch |
|---|---|---|
| Example 1 | 23.6 | 25.1 |
| Example 2 | 23.5 | 25.3 |
| Comparative Example | 28.4 | 30.2 |

Referring to Table 5, the hardmasks of the hardmask compositions of Examples 1 to 2, compared with that of the hardmask composition of the Comparative Example, exhibited a low etch rate during the N₂/O₂ mixed gas and CFx gas etching. It may be seen that the hardmask layers of the compositions of the Examples had excellent etch resistance compared with that of the hardmask composition of the Comparative Example.

By way of summation and review, according to small-sizing the pattern to be formed, it could be difficult to provide a fine pattern having an excellent profile by only some lithographic techniques. Accordingly, an auxiliary layer, called a hardmask layer, may be formed between the material layer and the photoresist layer to provide a fine pattern.

One or more embodiments may provide a hardmask composition that may be effectively applied to a hardmask layer.

A hardmask layer formed from a hardmask composition according to some embodiments may help secure excellent film density and film strength while not deteriorating solubility in a solvent.

A hardmask layer formed from the hardmask composition according to some embodiments may help secure excellent etch resistance.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent, 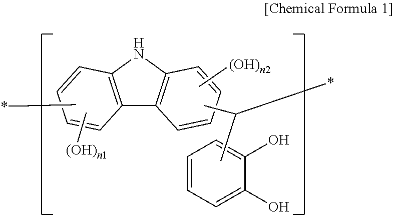
wherein, in Chemical Formula 1,
n1 and n2 are each independently 0 or 1,
n1+n2 is 1 or 2, and
is a linking point.

2. The hardmask composition as claimed in claim 1, wherein n1 is 0 and n2 is 1.

3. The hardmask composition as claimed in claim 1, wherein:
the polymer further includes a structural unit represented by Chemical Formula 2, 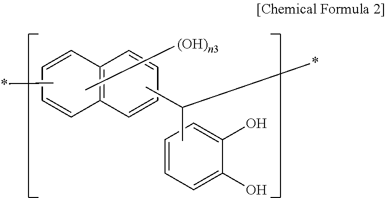
in Chemical Formula 2,
n3 is an integer of 1 to 6, and
is a linking point.

4. The hardmask composition as claimed in claim 3, wherein n3 is 1 or 2.

5. The hardmask composition as claimed in claim 3, wherein Chemical Formula 2 is represented by Chemical Formula 2-1, in which * is a linking point,

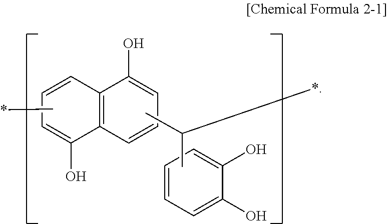

6. The hardmask composition as claimed in claim 1, wherein Chemical Formula 1 is represented by Chemical Formula 1-1 or Chemical Formula 1-2, in which * is a linking point,

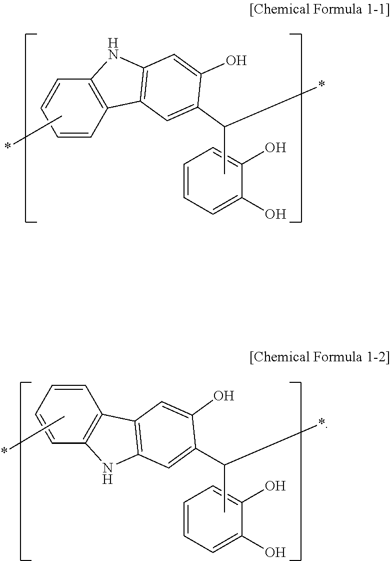

7. The hardmask composition as claimed in claim 1, wherein Chemical Formula 1 is represented by Chemical Formula 1-3 or Chemical Formula 1-4, in which * is a linking point,

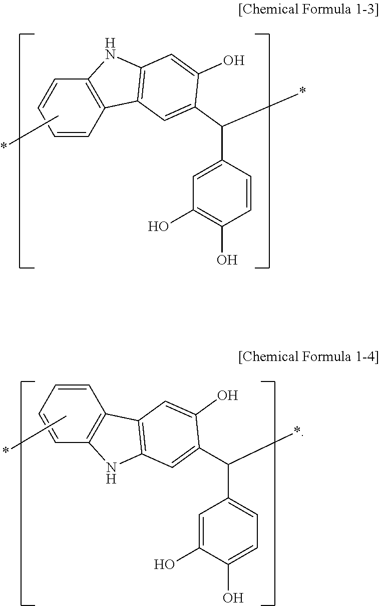

8. The hardmask composition as claimed in claim 1, wherein the polymer has a weight average molecular weight of about 1,000 g/mol to about 200,000 g/mol.

9. The hardmask composition as claimed in claim 1, wherein the polymer is included in an amount of about 0.1 wt % to about 30 wt %, based on a total weight of the hardmask composition.

10. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, N-methyl-2-pyrrolidone, acetylacetone, or ethyl 3-ethoxypropionate.

11. A hardmask layer comprising a cured product of the hardmask composition as claimed in claim 1.

12. A method of forming patterns, the method comprising:
providing a material layer on a substrate,
applying the hardmask composition as claimed in claim 1 to the material layer,
heat-treating the hardmask composition to form a hardmask layer,
forming a photoresist layer on the hardmask layer,
exposing and developing the photoresist layer to form a photoresist pattern,
selectively removing the hardmask layer using the photoresist pattern to expose a portion of the material layer, and
etching an exposed part of the material layer.

13. The method as claimed in claim 12, wherein the heat-treating is performed at about 100° C. to about 1,000° C.
